(19) United States
(12) Patent Application Publication
(10) Pub. No.: US 2024/0283678 A1
(43) Pub. Date: Aug. 22, 2024

(54) APPARATUS AND METHOD FOR EQUALIZING A DIGITAL INPUT SIGNAL, RECEIVER, BASE STATION AND MOBILE DEVICE

(71) Applicant: Intel Corporation, Santa Clara, CA (US)

(72) Inventors: Albert MOLINA, Novelda (ES); Kameran AZADET, San Ramon, CA (US); Martin CLARA, Santa Clara, CA (US)

(21) Appl. No.: 18/568,869

(22) PCT Filed: Dec. 22, 2021
(86) PCT No.: PCT/US2021/073068

§ 371 Date: Dec. 11, 2023

(51) Int. Cl. H04L 25/03; H03M 1/06; H03M 1/12

(52) U.S. Cl. CPC H04L 25/03127; H03M 1/0626; H03M 1/1215; H04L 2025/03509

(57) ABSTRACT

An apparatus for equalizing a digital input signal is provided. The apparatus includes an input node configured to receive the digital input signal. Further, the apparatus includes a plurality of filters coupled in parallel to the input node. The plurality of filters are configured to filter the digital input signal and generate a respective filtered signal. Additionally, the apparatus includes a combiner circuit coupled to the plurality of filters. The combiner circuit is configured to receive the respective filtered signal from the plurality of filters, and to generate an equalized signal by combining the received filtered signals according to a non-linear equalization function.

### BACKGROUND

Impairments of an analog circuitry and/or component may be mitigated or compensated digitally by implementing an equalizer to enhance the performance of such component at a reduced power consumption. An example of such analog component may be an Analog-to-Digital Converter (ADC) such as a time-interleaved ADC. The main impairments of a time-interleaved ADC are buffer and sampler nonlinearity, DC offset mismatch amongst sub-ADCs, and frequency response mismatch amongst sub-ADCs (gain and skew mismatch are included in this category).

A conventional equalizer uses the ADC output signal as input and needs to use cross-terms as its basis functions, which leads to increased complexity.

Ensuring that the performance is met by analog implementation may result in a significant increase of the analog component's power consumption. Accordingly, it may be necessary to increase the number and magnitude of the power supplies

Hence, there may be a demand for improved equalization in the digital domain.

### BRIEF DESCRIPTION OF THE FIGURES

Some examples of apparatuses and/or methods will be described in the following by way of example only, and with reference to the accompanying figures, in which

FIG. 1 illustrates an exemplary system comprising an analog component and an example of an apparatus for equalizing a digital input signal;

FIG. 2 illustrates another system comprising an analog component and an example of an apparatus for equalizing a digital input signal;

FIG. 3 illustrates an example of an apparatus for equalizing a digital input signal;

FIG. 4 illustrates a system comprising an analog component and an equalizer;

FIG. 5 illustrates an alternative representation of the apparatus illustrated in FIG. 3;

FIG. 6 illustrates an example of abase station;

FIG. 7 illustrates an example of a mobile device; and

FIG. 8 illustrates flowchart of an example of a method for equalizing a digital input signal.

### DETAILED DESCRIPTION

Some examples are now described in more detail with reference to the enclosed figures. However, other possible examples are not limited to the features of these embodiments described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, i.e. only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

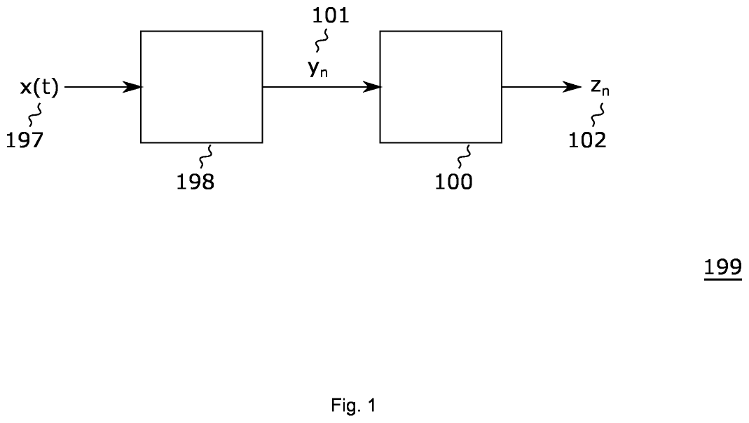

FIG. 1 illustrates a system 199 comprising a non-linear analog system (component, circuitry) 198 such as an ADC (e.g. a time-interleaved ADC). An analog signal x(t), which is referenced by reference sign 197, is distorted by the non-linear analog system 198. The nonlinear analog system 198 outputs a digital signal y(n), which is referenced by reference sign 101. For example, if the non-linear analog system 198 is or comprises a time-interleaved ADC, buffer and sampler nonlinearity, DC offset mismatch amongst sub-ADCs, and frequency response mismatch amongst sub-ADCs may distort the analog signal 197 and, hence, cause distortions in the digital signal 101. It is to be noted that the ADC could also have linear impairments (it may, e.g., have a non-ideal linear frequency response).

The digital signal 101 is an input signal for an apparatus 100. The apparatus 100 is for equalizing the digital input signal 101. In other words, the apparatus 100 may be understood as an equalizer. Accordingly, the apparatus 100 outputs an equalized (digital) signal z(n), which is referenced by reference sign 102.

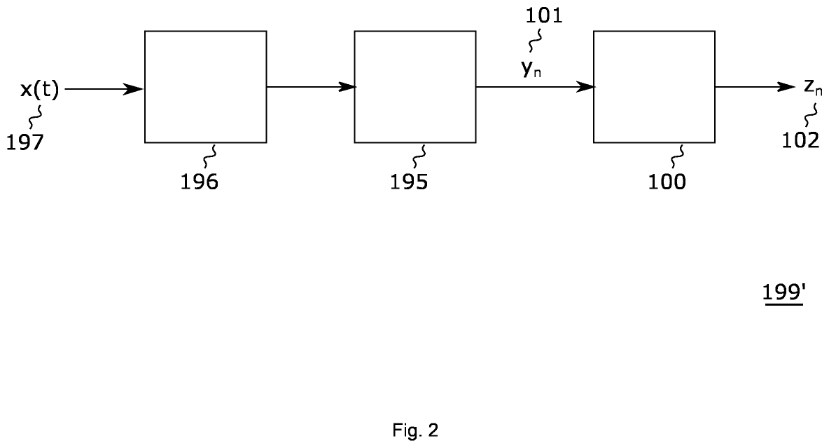

FIG. 2 illustrates another system 199′, which is equivalent to the system 199 illustrated in FIG. 1. In the example of FIG. 2, a non-linear analog system (component, circuitry) 196 is followed by an ideal ADC 195. In case the ADC is a time-interleaved ADC, the differences in the linear and nonlinear behavior of the different sub-ADCs would manifest itself as a cyclostationarity of the nonlinear system 196 preceding the ideal ADC 195. Again, the apparatus 100 is used for equalizing the digital input signal 101 output by the ideal ADC 195.

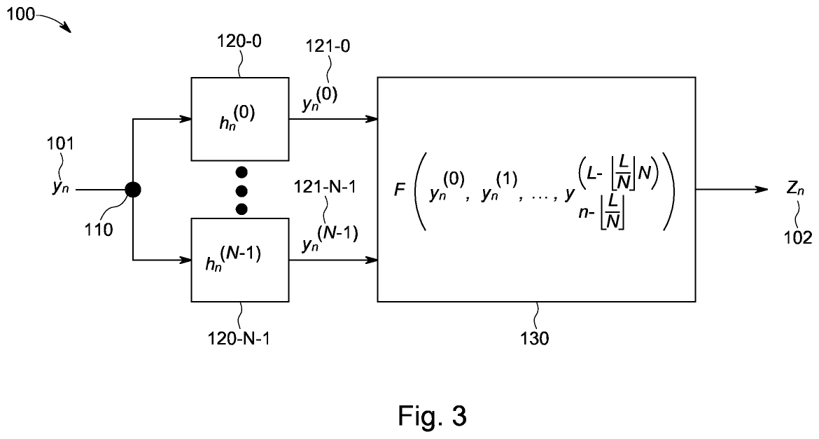

The apparatus 100 for equalizing the digital input signal 101 will be explained in the following with reference to FIGS. 3 to 5. Although some passages of the following description focus on input signals bandlimited to the first Nyquist zone (i.e. from 0 Hz to F_{S}/2 Hz with F_{S} denoting the value of the ADCs sample rate), it is to be noted that the proposed equalization technique may as well be used for signals covering a different Nyquist zone.

FIG. 3 illustrates an example of an apparatus 100 for equalizing the digital input signal 101. The apparatus 100 comprises an input node 110 configured to receive the digital input signal 101.

Further, the apparatus 100 comprises a plurality of filters (filter circuits) 120-0, . . . , 120-N-1 coupled to the input node 110. In FIG. 3, exactly two filters 120-0 and 120-N-1 are illustrated. However, in general, the apparatus 100 may comprise any number N≥2 of filters. The plurality of filters 120-0, . . . , 120-N-1 are coupled in parallel. A respective input of each of the plurality of filters 120-0, . . . , 120-N-1 is coupled to the input node 110. The plurality of filters 120-0, . . . , 120-N-1 are each configured to filter the digital input signal 101 and to generate and output a respective filtered signal 121-0, . . . , 121-N-1.

As indicated in FIG. 3, each of the plurality of filters 120-0, . . . , 120-N-1 exhibits a respective impulse response function hₙ⁽⁰⁾, . . . , hₙ^{(N-1)} defined by one or more filter coefficient of the respective filter. The superscript of each impulse response function hₙ⁽⁰⁾, . . . , hₙ^{(N-1)} denotes a respective one of the N filters 120-0, . . . , 120-N-1. Each of the filtered signals 121-0, . . . , 121-N-1 comprises respective samples yₙ⁽⁰⁾, . . . , yₙ^{(N-1)} The superscript of each of yₙ⁽⁰⁾, . . . , yₙ^{(N-1)} denotes a respective one of the N received filtered signals 121-0, . . . 121-N-1. The filtered signals 121-0, . . . , 121-N-1 may be understood as polyphases of the digital input signal 101.

The apparatus 100 additionally comprises a combiner circuit 130 coupled to the plurality of filters 120-0, . . . , 120-N-1. In particular, the combiner circuit 130 is coupled to a respective output of each of the plurality of filters 120-0, . . . , 120-N-1. The combiner circuit 130 is configured to receive the respective filtered signal 121-0, . . . , 121-N-1 from the plurality of filters 120-0, . . . , 120-N-1. Further, the combiner circuit 130 is configured to generate the equalized signal 102 by combining the received filtered signals 121-0, . . . , 121-N-1 according to a non-linear equalization function F. A sample rate of the equalized signal 102 is equal to a sample rate of the digital input signal 101.

Filtering the digital input signal 101 by the plurality of filters 120-0, . . . , 120-N-1 and subsequently combining the filtered signals 121-0, . . . , 121-N-1 may allow to reduce the complexity of the combination operation performed by the combiner circuit 130 compared to conventional approaches. For example, the apparatus 100 may allow to omit using cross-terms as basis functions for the combination operation performed by the combiner circuit 130. Accordingly, the apparatus 100 may enable improved digital equalization allowing to meet high performance targets at lower power consumption and lower area consumption.

The equalization function F may be a combination of a plurality of basis functions ƒ. For example, in case a memory depth of the equalization function F is L, the combiner circuit 130 may be configured to determine a vector comprising L+1 samples from the received filtered signals 121-0, . . . , 121-N-1 as entries. L is an integer number. Further, the combiner circuit 130 may be configured to input the vector into the plurality of basis functions ƒ and to combine outputs of the plurality of basis functions ƒ for the input vector to generate a sample of the equalized signal. The memory depth of the equalization function F is a quantity specifying how many samples are considered by the equalization function F and consequently to which extent the equalization function F considers samples preceding a current sample position n. One or more of the basis functions ƒ may be a non-linear function. In some example, all of the basis functions ƒ may be non-linear functions. In other examples, all of the basis functions ƒ may be linear functions. The combiner circuit 130 may, e.g., linearly combine the outputs of the plurality of basis functions ƒ for the input vector.

The above processing may be expressed in terms of a mathematical expression which is equivalent to:

$${z}_{n} = {\sum }_{k} {β}_{k} {f}_{k} ( {y}_{n}^{( 0 )} , {y}_{n}^{( 1 )} , … , {y}_{n - ⌊ \frac{L}{N} ⌋}^{( L - ⌊ \frac{L}{N} ⌋ N )} ) \qquad ( 1 )$$

In other words, the combiner circuit 130 may be configured to generate the equalized signal 102 according to a mathematical expression which is equivalent to the above mathematical expression (1). In mathematical expression (1), zₙ denotes a sample of the equalized signal 102, ƒₖ denotes a respective one of the plurality of basis functions, βₖ denotes a respective weight,

$${y}_{n}^{( 0 )} , {y}_{n}^{( 1 )} , … , {y}_{n - ⌊ \frac{L}{N} ⌋}^{( L - ⌊ \frac{L}{N} ⌋ N )}$$

denotes the L+1 samples of the received filtered signals 121-0, . . . , 121-N-1 forming the vector, N denotes the number of the filters coupled in parallel, the subscript of each of zₙ and

$${y}_{n}^{( 0 )} , {y}_{n}^{( 1 )} , … , {y}_{n - ⌊ \frac{L}{N} ⌋}^{( L - ⌊ \frac{L}{N} ⌋ N )}$$

denotes a respective sample position of the respective sample, and the superscript of each of

$${y}_{n}^{( 0 )} , {y}_{n}^{( 1 )} , … , {y}_{n - ⌊ \frac{L}{N} ⌋}^{( L - ⌊ \frac{L}{N} ⌋ N )}$$

denotes respective one of the N received filtered signals 121-0, . . . , 121-N-1.

As can be seen from mathematical expression (1), the combiner circuit 130 may be configured to combine the outputs of the plurality of basis functions ƒ using a respective weight βfor the outputs of the plurality of basis functions.

Further, it be seen from mathematical expression (1) that the structure of the vector depends on the memory depth L of the equalization function F and the number N of the filters 120-0, . . . , 120-N-1 coupled in parallel. If L<N, the vector comprises a respective sample at a sample position n from L+1 different ones of the received filtered signals 121-0, . . . , 121-N-1 as entries. For example, if L=1 and N=2, the vector comprises the samples yₙ⁽⁰⁾) and yₙ⁽¹⁾ as entries. On the other hand, if L≥N, the vector comprises a respective sample at the sample position n from N different ones of the received filtered signals 121-0, . . . 121-N-1 and L+1−N samples of different ones of the received filtered signals 121-0, . . . , 121-N-1 at one or more sample position preceding the sample position n as entries. For example, if L=2 and N=2, the vector comprises the samples yₙ⁽⁰⁾, yₙ⁽¹⁾ and yₙ₋₁⁽⁰⁾ as entries. If L=5 and N=2, the vector comprises the samples yₙ⁽⁰⁾, yₙ⁽¹⁾, yₙ₋₁⁽⁰⁾, yₙ₋₁⁽¹⁾, yₙ₋₂⁽⁰⁾ and yₙ₋₂⁽¹⁾ as entries. In other words, the vector comprises L+1 consecutive samples of the received filtered signals 121-0, . . . , 121-N-1.

The respective impulse response function hₙ⁽⁰⁾, . . . , hₙ^{(N-1)} of each of the plurality of filters 120-0, . . . , 120-N-1 may be fixed. In other words, the respective impulse response function hₙ⁽⁰⁾, . . . , hₙ^{(N-1)} of each of the plurality of filters 120-0, . . . , 120-N-1 may be predetermined and cannot be altered.

As described above, any number of filters may be used. Similarly, the plurality of filters 120-0, . . . , 120-N-1 may exhibit any frequency response appropriate to match the system being equalized or tailored to the range of input frequencies covered by the digital input signal 101. In other words, the plurality of filters 120-0, . . . , 120-N-1 may exhibit any respective impulse response function hₙ⁽⁰⁾, . . . , hₙ^{(N-1)}.

In some examples, the plurality of filters 120-0, . . . , 120-N-1 are fractional delay filters. In other words, the plurality of filters 120-0, . . . , 120-N-1 may be configured to delay the digital input signal 101 by a respective fractional of a sampling period time of the digital input signal 101. The delays of the individual filters may be equally spaced in the time domain among the plurality of filters 120-0, . . . , 120-N-1 according to some examples. In other words, the delays of the individual filters 120-1, . . . , 120-N-1 may differ from the delay of the filter 120-0 by p·Δt with p=1, 2, 3 . . . and Δt being a predetermined (given) time difference. However, it is to be noted that the present disclosure is not limited thereto. In other examples, delays of the individual filters may be unequally spaced in the time domain among the plurality of filters 120-0, . . . , 120-N-1. In other words, the delays of the individual filters may differ from each other by arbitrary time differences.

In some examples, one of the plurality of fractional delay filters 120-0, . . . , 120-N-1 may be configured to delay the digital input signal 101 by zero times the sampling period time of the digital input signal. In other words, one of the plurality of fractional delay filters 120-0, . . . , 120-N-1 may be configured to not delay the digital input signal 101. Accordingly, if N=2, the digital input signal 101 may effectively be delayed by only one fixed fractional delay filter.

Using fractionally delayed replicas of the digital input signal 101 may allow to reduce the complexity of the combination operation performed by the combiner circuit 130 compared to conventional approaches. As described above, the fractional delaying of the digital input signal 101 may allow to omit using cross-terms as basis functions for the combination operation performed by the combiner circuit 130.

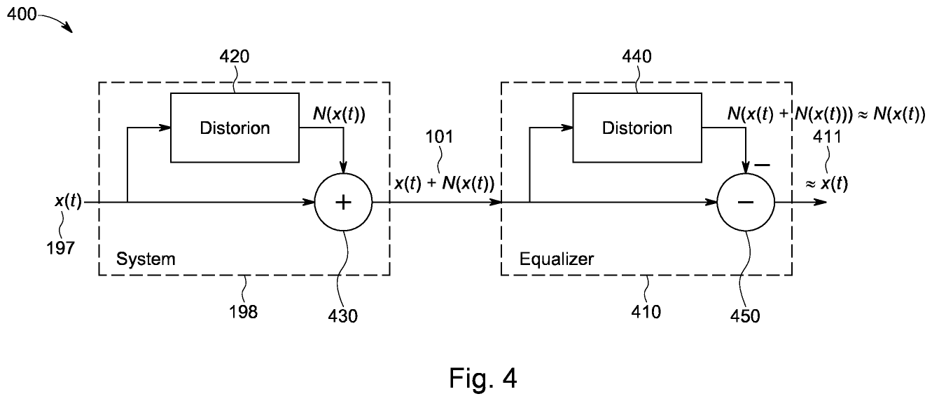

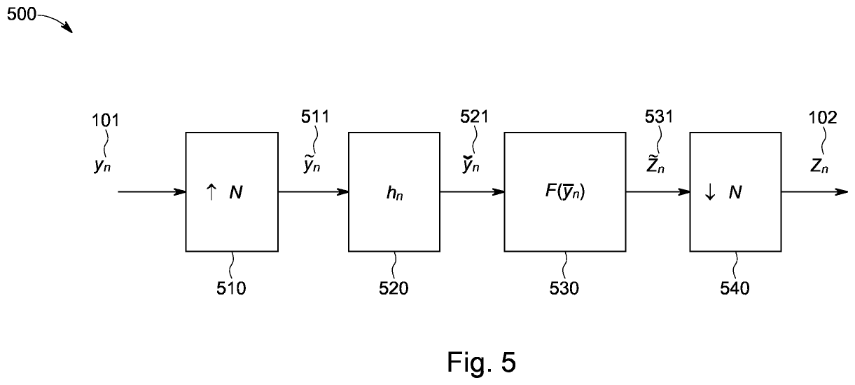

A derivation of the structure of the apparatus 100 will be given below with respect to FIGS. 4 and 5.

FIG. 4 illustrates a system 400 similar to the system 199 illustrated in FIG. 1. The system 400 comprises the non-linear analog system 198 described above. For example, the non-linear analog system 198 may be an ADC. The non-linear analog system 198 introduces some distortion to the input signal x(t), which is again referenced by the reference sign 197. The distortion may consist of linear and/or non-linear effects. The distorting components of the non-linear analog system 198 are schematically represented by the distortion block 420 in FIG. 4. The distortion N(x(t)) is a function of the input signal 197. The digital signal 101 output by the non-linear analog system 198 is effectively the sum of the input signal 197 and the distortion N(x(t)). Accordingly, the digital signal 101 output by the non-linear analog system 198 is the digitized replica of x(t)+N(x(t)). The summing of the input signal 197 and the distortion N(x(t)) in the non-linear analog system 198 is represented by a summation block 430 in FIG. 4.

For a mild distortion, the equalizer 410 coupled to the non-linear analog system 198 may have a similar structure like the non-linear analog system 198. Similar to what is described above for the non-linear analog system 198, the equalizer 410 causes a distortion of the digital signal 101 such that N(x(t)+N(x(t)))≈N(x(t)). The distortion components of the equalizer 410 are schematically represented by the distortion block 440 in FIG. 4. Accordingly, by subtracting the distortion generated by the equalizer 410 from the digital signal 101, the distortion N(x(t)) caused by the non-linear analog system 198 may be compensated for a mild distortion such that the output 411 of the equalizer 410 is ≈x(t). The subtraction of the distortion N(x(t)) generated by the equalizer 410 from the digital signal 101 in the equalizer 410 is represented by a subtraction block 450 in FIG. 4.

For a non-linear system comprising an analog non-linearity followed by a sampler (e.g. a non-linear system comprising or being an ADC), the nonlinear process increases the bandwidth of the input signal. Hence, even if the input signal is bandlimited to the first Nyquist zone, the sampling process introduces aliasing. As explained above, an equalizer may have a structure similar to those of the system that it is aiming to equalize. This is achieved by the apparatus 100 described above. FIG. 5 illustrates an alternative representation of the apparatus 100 illustrated in FIG. 3, where the filters hₖ^{(m)}, m=0 . . . N−1 are uniformly spaced fractional delay filters, i.e., with fractional delays mTₛ/N, where Tₛ is the sampling period.

The alternative representation consists of an upsampling (interpolation) block (circuit) 510 configured to upsample (interpolate) the digital input signal 101 by the factor N. The upsampling (interpolation) block 510 outputs an upsampled digital input signal 511, which approximates the analog signal from which the digital input signal 101 is derived. The analog signal may be understood as a digital signal with infinite oversampling. The upsampling block 510 is followed by a filter block (circuit) 520 configured to filter the upsampled digital input signal 511 and output a filtered signal 521. The filter block 520 is followed by a functional block (circuit) 530. The functional block 530 implements a non-linear function F(y̅ₙ) of a vector of present and previous samples of the filtered signal 521. Finally, the functional block 530 is followed a downsampling (decimation) block (circuit) 540 configured to downsample the output signal 531 of the functional block 530 by the factor N. The output of the downsampling block 540 is the equalized signal 102.

In other words, yₙ is the equalizer input and \check{y}ₙ is an interpolated version of yₙ, which approximates the analog signal (that has an infinite oversampling). F(y̅ₙ) is a nonlinear function of a vector y̅ⁿ of present and previous samples of \check{y}, and zₙ is a down-sampled version of the equalizer output. The structure of FIG. 5 may be expressed in mathematical form as follows:

$${\tilde{y}}_{n} = \{ \begin{matrix}{y}_{n / N} & n / N = 0 \\ 0 & n / N \neq 0\end{matrix} \qquad ( 2 )$$

$${\check{y}}_{n} = {\sum }_{k} {h}_{k} {\tilde{y}}_{n - k} \qquad ( 3 )$$

$${\overline{y}}_{n} = ( {\check{y}}_{n} , {\check{y}}_{n - 1} , … , {\check{y}}_{n - L} ) \qquad ( 4 )$$

$${\tilde{z}}_{n} = F ( {\overline{y}}_{n} ) = {\sum }_{k} {β}_{k} {f}_{k} ( {\overline{y}}_{n} ) \qquad ( 5 )$$

$${z}_{n} = {\tilde{z}}_{n N} \qquad ( 6 )$$

The upsampling (interpolation) process can be expressed in polyphase form. The m^{th} phase of \check{y}ₙ is

$${y}_{n}^{( m )} = {\check{y}}_{n N - m} = {\sum }_{k} {h}_{k}^{( m )} {y}_{n - k} m ∈ \{ 0 , … , N - 1 \} \qquad ( 7 )$$

$$where$$

$${h}_{k}^{( m )} = {h}_{k N - m} m ∈ \{ 0 , … , N - 1 \} \qquad ( 8 )$$

is the m^{th} phase of hₖ. As described above, each hₖ^{(m)} may, e.g., approximate a fractional delay filter of delay m/N.

The non-linear function F(y̅ₙ) may be expressed as follows in terms of the polyphase representation of \check{y}ₙ:

$${\overline{y}}_{n} = ( {\check{y}}_{n} , {\check{y}}_{n - 1} , … , {\check{y}}_{n - L} ) \qquad ( 9 )$$

with

$$n = lN - m \qquad ( 10 )$$

$$and$$

$${y}_{l}^{( m )} = {\check{y}}_{l N - m} \qquad ( 11 )$$

wherein

$$l = ⌈ \frac{n}{N} ⌉ \qquad ( 12 )$$

$$m = ⌈ \frac{n}{N} ⌉ N - n \qquad ( 13 )$$

$$and$$

$${y}_{⌈ \frac{n}{N} ⌉}^{( ⌈ \frac{n}{N} ⌉ N - n )} = {\check{y}}_{n} \qquad ( 14 )$$

with ┌, . . . ┘ denoting the ceiling function.

Accordingly, the vector y̅ₙ may be expressed as follows:

$${\overline{y}}_{n} = ( {y}_{⌈ \frac{n}{N} ⌉}^{( ⌈ \frac{n}{N} ⌉ N - n )} , {y}_{⌈ \frac{n - L}{N} ⌉}^{( ⌈ \frac{n - 1}{N} ⌉ N - n + 1 )} , … , {y}_{⌈ \frac{n - L}{N} ⌉}^{( ⌈ \frac{n - L}{N} ⌉ N - n + L )} ) \qquad ( 15 )$$

such that the equalized signal may be expressed as follows:

$${z}_{n} = {\sum }_{k} {β}_{k} {f}_{k} ( {\overline{y}}_{nN} ) = {\sum }_{k} {β}_{k} {f}_{k} ( {y}_{⌈ \frac{nN}{N} ⌉}^{( ⌈ \frac{nN}{N} ⌉ N - nN )} , {y}_{⌈ \frac{nN - 1}{N} ⌉}^{( ⌈ \frac{n N - 1}{N} ⌉ N - nN + 1 )} , … , {y}_{⌈ \frac{nN - L}{N} ⌉}^{( ⌈ \frac{nN - L}{N} ⌉ N - nN + L )} ) \qquad ( 16 )$$

$${z}_{n} = {\sum }_{k} {β}_{k} {f}_{k} ( {y}_{n}^{( 0 )} , {y}_{n}^{( 1 )} , … , {y}_{n - ⌊ \frac{L}{N} ⌋}^{( L - ⌊ \frac{L}{N} ⌋ N )} ) \qquad ( 17 )$$

$${z}_{n} = F ( {y}_{n}^{( 0 )} , {y}_{n}^{( 1 )} , … , {y}_{n - ⌊ \frac{L}{N} ⌋}^{( L - ⌊ \frac{L}{N} ⌋ N )} ) \qquad ( 18 )$$

It is evident from the above mathematical expressions that the structure of the apparatus 100 illustrated in FIG. 3 is identical/equivalent to the structure illustrated in FIG. 5. While the blocks 520 and 530 operate a high data rate of N times the digital input signal 101's sample rate, all blocks of the apparatus 100 operate at the lower sample rate of the digital input signal 101, which allows to save power. The upsampling illustrated in FIG. 5 is effectively achieved by the apparatus 100 by the N parallel filters 120-0, . . . , 120-N-1. Accordingly, the output of the apparatus 100 is effectively a non-linear function (combination) of the outputs of several filters 120-0, . . . , 120-N-1 (e.g. delay approximation filters such a fractional delay filters).

As an example, one may consider a case where an analog system may be described by the following equation:

$$y ( t ) = {α}_{1} x ( t ) + {α}_{3} {x}^{3} ( t - {t}_{3} ) \qquad ( 23 )$$

$$y ( t ) = {α}_{1} x ( t ) + {{α}_{3} ( x ( t ) * δ ( t - {t}_{3} ) )}^{3} \qquad ( 24 )$$

Since x(t) is bandlimited, one may filter it with a filter whose frequency response is

$$S ( f ) = \{ \begin{matrix}1 & 0 \leq \vert f \vert \leq \frac{{F}_{s}}{2} \\ 0 & Otherwise\end{matrix} \qquad ( 25 )$$

It may be shown that the impulse response is

$$s ( t ) = {F}_{s} \frac{sin ( π {F}_{s} t )}{π {F}_{s} t} = {F}_{s} sin c ( π {F}_{s} t ) \qquad ( 26 )$$

Therefore

$$y ( t ) = {α}_{1} x ( t ) + {{α}_{3} ( x ( t ) * s ( t - {t}_{3} ) )}^{3} \qquad ( 27 )$$

It may be shown that the sequence of samples

$${y}_{n} = y ( n {T}_{s} ) = {α}_{1} {x}_{n} + {α}_{3} {( {\sum }_{k = - ∞}^{∞} sin c ( π ( k - {t}_{3} {F}_{s} ) ) {x}_{n - k} )}^{3} \qquad ( 28 )$$

$${y}_{n} = {α}_{1} {x}_{n} + {α}_{3} {\sum }_{{k}_{3}} {\sum }_{{k}_{2}} {\sum }_{{k}_{1}} sin c ( π ( k - {t}_{3} {F}_{s} ) ) sin c ( π ( k - {t}_{3} {F}_{s} ) ) sin c ( π ( k - {t}_{3} {F}_{s} ) ) {x}_{n - {k}_{1}} {x}_{n - {k}_{2}} {x}_{n - {k}_{3}} \qquad ( 29 )$$

As can be seen from the above equations, this model contains cross-terms. If an equalizer was implemented mimicking this equation, i.e., as

$${z}_{n} = {β}_{1} {y}_{n} + {\sum }_{{k}_{3}} {\sum }_{{k}_{2}} {\sum }_{{k}_{1}} {β}_{{k}_{1} {k}_{2} {k}_{3}} {x}_{n - {k}_{1}} {x}_{n - {k}_{2}} {x}_{n - {k}_{3}} \qquad ( 30 )$$

then it would contain many cross-terms, which results in a complex implementation. Also, if a coefficient is assigned to each cross-term, then the number of equalizer coefficients would be large. Instead, the proposed architecture allows to implement the equalizer (i.e. the apparatus 100) as follows:

$${y}_{n}^{( 0 )} = {y}_{n} \qquad ( 31 )$$

$${y}_{n}^{( 1 )} = {\sum }_{k = - ∞}^{∞} sinc ( π ( k - {t}_{3} {F}_{s} ) ) {x}_{n - k} \qquad ( 32 )$$

such that

$${z}_{n} = {β}_{1} {y}_{n}^{( 0 )} + {β}_{1} {y}_{n}^{( 1 )} \qquad ( 33 )$$

As can be seen when comparing mathematical expressions (30) and (33), the proposed equalization architecture may enable improved digital equalization with reduced complexity as the proposed equalization allows to avoid using cross-terms as its basis functions.

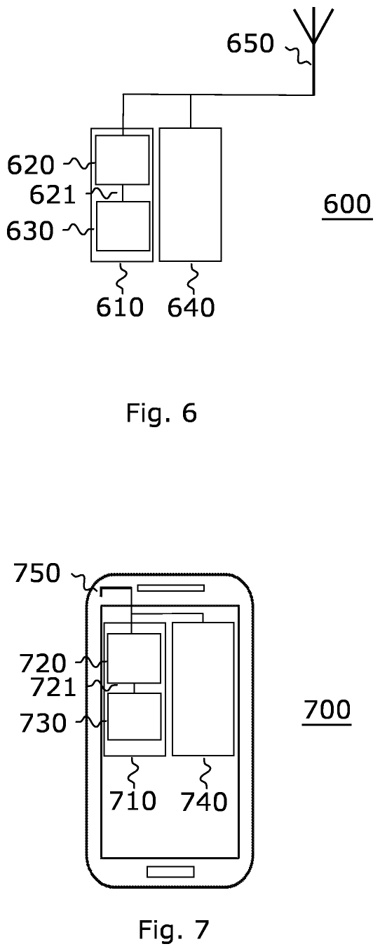

An example of an implementation using equalization according to one or more aspects of the architecture described above in connection with FIGS. 1 to 5 or one or more examples described above in connection with FIGS. 1 to 5 is illustrated in FIG. 6. FIG. 6 schematically illustrates an example of a radio base station 600 (e.g. for a femtocell, a picocell, a microcell or a macrocell) comprising an apparatus 630 for equalizing a digital input signal 621 as proposed.

The base station 600 comprises at least one antenna element 650. A receiver 610 of the base station 600 comprises the apparatus 630 and is coupled to the antenna element 650. For example, the receiver 610 may be coupled to the antenna element 650 via one or more intermediate element such as a Low-Noise Amplifier (LNA), a filter, a down-converter (mixer), Electro Static Discharge (ESD) protection circuitry, an attenuator etc.

Additionally, the receiver 610 comprises a non-linear system 620 coupled to the apparatus 630. The non-linear system 610 provides the digital input signal 621. The non-linear system 620 may, e.g., be configured to generate the digital input signal 621 based on a Radio Frequency (RF) receive signal received from the antenna element 650 or another antenna element (not illustrated) of the base station 600. The non-linear system 620 may be or comprise an ADC configured to output the digital input signal 621. The non-linear system 620 may comprise one or more further element such as a LNA, a filter, a down-converter (mixer), ESD protection circuitry, an attenuator, etc.

Additionally, the base station 600 comprises a transmitter 640 configured to generate a RF transmit signal. The transmitter 640 may use the antenna element 650 or another antenna element (not illustrated) of the base station 600 for radiating the RF transmit signal to the environment. For example, the transmitter 640 may be coupled to the antenna element 650 via one or more intermediate elements such as a filter, an up-converter (mixer) or a Power Amplifier (PA).

To this end, a base station with improved digital equalization may be provided allowing the base station to meet high performance targets at lower power consumption and lower area consumption.

The base station 600 may comprise further elements such as, e.g., an application processor, memory, a network controller, a user interface, power management circuitry, a satellite navigation receiver, a network interface controller or power tee circuitry.

In some aspects, the application processor may include one or more Central Processing Unit CPU cores and one or more of cache memory, a Low-DropOut (LDO) voltage regulator, interrupt controllers, serial interfaces such as Serial Peripheral Interface (SPI), Inter-Integrated Circuit (I²C) or universal programmable serial interface module, Real Time Clock (RTC), timer-counters including interval and watchdog timers, general purpose Input-Output (IO), memory card controllers such as Secure Digital (SD)/MultiMedia Card (MMC) or similar, Universal Serial Bus (USB) interfaces, Mobile Industry Processor Interface Alliance (MIPI) interfaces and Joint Test Access Group (JTAG) test access ports.

In some aspects, the baseband processor may be implemented, for example, as a solder-down substrate including one or more integrated circuits, a single packaged integrated circuit soldered to a main circuit board or a multi-chip module containing two or more integrated circuits.

In some aspects, the memory may include one or more of volatile memory including Dynamic Random Access Memory (DRAM) and/or Synchronous Dynamic Random Access Memory (SDRAM), and Non-Volatile Memory (NVM) including high-speed electrically erasable memory (commonly referred to as Flash memory), Phase change Random Access Memory (PRAM), Magnetoresistive Random Access Memory (MRAM) and/or a three-dimensional crosspoint (3D XPoint) memory. The memory may be implemented as one or more of solder down packaged integrated circuits, socketed memory modules and plug-in memory cards.

In some aspects, the power management integrated circuitry may include one or more of voltage regulators, surge protectors, power alarm detection circuitry and one or more backup power sources such as a battery or capacitor. Power alarm detection circuitry may detect one or more of brown out (under-voltage) and surge (over-voltage) conditions.

In some aspects, the power tee circuitry may provide for electrical power drawn from a network cable to provide both power supply and data connectivity to the base station using a single cable.

In some aspects, the network controller may provide connectivity to a network using a standard network interface protocol such as Ethernet. Network connectivity may be provided using a physical connection which is one of electrical (commonly referred to as copper interconnect), optical or wireless.

In some aspects, the satellite navigation receiver module may include circuitry to receive and decode signals transmitted by one or more navigation satellite constellations such as the Global Positioning System (GPS), GLObalnaya NAvigatSionnaya Sputnikovaya Sistema (GLONASS), Galileo and/or BeiDou. The receiver may provide data to the application processor which may include one or more of position data or time data. The application processor may use time data to synchronize operations with other radio base stations.

In some aspects, the user interface may include one or more of physical or virtual buttons, such as a reset button, one or more indicators such as Light Emitting Diodes (LEDs) and a display screen.

Another example of an implementation using equalization according to one or more aspects of the architecture described above in connection with FIGS. 1 to 5 or one or more examples described above in connection with FIGS. 1 to 5 is illustrated in FIG. 7. FIG. 7 schematically illustrates an example of a mobile device 700 (e.g. mobile phone, smartphone, tablet-computer, or laptop) comprising an apparatus 730 for equalizing a digital input signal 621 as proposed.

The mobile device 700 comprises at least one antenna element 750. A receiver 710 of the mobile device 700 comprises the apparatus 730 and is coupled to the antenna element 750. For example, the receiver 710 may be coupled to the antenna element 750 via one or more intermediate element such as a LNA, a filter, a down-converter (mixer), ESD protection circuitry, an attenuator etc.

Additionally, the receiver 710 comprises a non-linear system 720 coupled to the apparatus 730. The non-linear system 710 provides the digital input signal 721. The non-linear system 720 may, e.g., be configured to generate the digital input signal 721 based on a RF receive signal received from the antenna element 750 or another antenna element (not illustrated) of the mobile device 700. The non-linear system 720 may be or comprise an ADC configured to output the digital input signal 721. The non-linear system 720 may comprise one or more further element such as a LNA, a filter, a down-converter (mixer), ESD protection circuitry, an attenuator, etc.

Additionally, the mobile device 700 comprises a transmitter 740 configured to generate a RF transmit signal. The transmitter 740 may use the antenna element 750 or another antenna element (not illustrated) of the mobile device 700 for radiating the RF transmit signal to the environment. For example, the transmitter 740 may be coupled to the antenna element 750 via one or more intermediate elements such as a filter, an up-converter (mixer) or a PA.

To this end, a mobile device with improved digital equalization may be provided allowing the mobile device to meet high performance targets at lower power consumption and lower area consumption.

The mobile device 700 may comprise further elements such as, e.g., a baseband processor, memory, a connectivity module, a Near Field Communication (NFC) controller, an audio driver, a camera driver, a touch screen, a display driver, sensors, removable memory, a power management integrated circuit or a smart battery.

In some aspects, the application processor may include, for example, one or more CPU cores and one or more of cache memory, LDO regulators, interrupt controllers, serial interfaces such as SPI, I²C or universal programmable serial interface module, RTC, timer-counters including interval and watchdog timers, general purpose input-output (IO), memory card controllers such as SD/MMC or similar, USB interfaces, MIPI interfaces and JTAG test access ports.

In some aspects, the baseband module may be implemented, for example, as a solder-down substrate including one or more integrated circuits, a single packaged integrated circuit soldered to a main circuit board, and/or a multi-chip module containing two or more integrated circuits.

The wireless communication circuits using equalization according to the proposed architecture or one or more of the examples described above may be configured to operate according to one of the 3rd Generation Partnership Project (3GPP)-standardized mobile communication networks or systems. The mobile or wireless communication system may correspond to, for example, a 5^{th} Generation New Radio (5G NR), a Long-Term Evolution (LTE), an LTE-Advanced (LTE-A), High Speed Packet Access (HSPA), a Universal Mobile Telecommunication System (UMTS) or a UMTS Terrestrial Radio Access Network (UTRAN), an evolved-UTRAN (e-UTRAN), a Global System for Mobile communication (GSM), an Enhanced Data rates for GSM Evolution (EDGE) network, or a GSM/EDGE Radio Access Network (GERAN). Alternatively, the wireless communication circuits may be configured to operate according to mobile communication networks with different standards, for example, a Worldwide Inter-operability for Microwave Access (WIMAX) network IEEE 802.16 or Wireless Local Area Network (WLAN) IEEE 802.11, generally an Orthogonal Frequency Division Multiple Access (OFDMA) network, a Time Division Multiple Access (TDMA) network, a Code Division Multiple Access (CDMA) network, a Wideband-CDMA (WCDMA) network, a Frequency Division Multiple Access (FDMA) network, a Spatial Division Multiple Access (SDMA) network, etc.

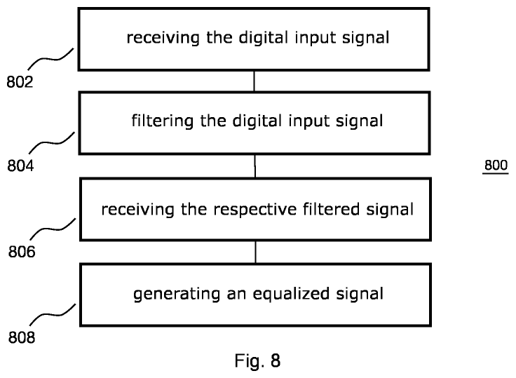

For further illustrating the equalization described above, FIG. 8 illustrates a flowchart of a method 800 for equalizing a digital input signal. The method 800 comprises receiving 802 the digital input signal at an input node. In addition, the method 800 comprises filtering 804 the digital input signal using a plurality of filters coupled in parallel to the input node to generate a respective filtered signal. Further, the method 800 comprise receiving 806 the respective filtered signal from the plurality of filters at a combiner circuit. The method 800 additionally comprises generating 808 an equalized signal using the combiner circuit by combining the received filtered signals according to a non-linear equalization function.

The method 800 may enable improved digital equalization allowing to meet high performance targets at lower power consumption and lower area consumption. As described above, equalization with reduced complexity may be enabled by the method 800 as the proposed equalization allows to avoid using cross-terms as its basis functions.

More details and aspects of the method 800 are explained in connection with the proposed technique or one or more examples described above (e.g. FIGS. 1 to 7). The method 800 may comprise one or more additional optional features corresponding to one or more aspects of the proposed technique or one or more examples described above.

The examples described herein may be summarized as follows:

An example (e.g. example 1) relates to an apparatus for equalizing a digital input signal, comprising: an input node configured to receive the digital input signal; a plurality of filters coupled in parallel to the input node, wherein the plurality of filters are configured to filter the digital input signal and generate a respective filtered signal; and a combiner circuit coupled to the plurality of filters and configured to: receive the respective filtered signal from the plurality of filters; and generate an equalized signal by combining the received filtered signals according to a non-linear equalization function.

Another example (e.g. example 2) relates to a previously described example (e.g. example 1), wherein a respective impulse response function of the plurality of filters is fixed.

Another example (e.g. example 3) relates to a previously described example (e.g. example 1 or example 2), wherein the plurality of filters are fractional delay filters.

Another example (e.g. example 4) relates to a previously described example (e.g. example 3), wherein the plurality of fractional delay filters are configured to delay the digital input signal by a respective fractional of a sampling period time of the digital input signal.

Another example (e.g. example 5) relates to a previously described example (e.g. example 3 or example 4), wherein one of the plurality of fractional delay filters is configured to delay the digital input signal by zero times the sampling period time of the digital input signal.

Another example (e.g. example 6) relates to a previously described example (e.g. any one of examples 1 to 5), wherein a sample rate of the equalized signal is equal to a sample rate of the digital input signal.

Another example (e.g. example 7) relates to a previously described example (e.g. any one of examples 1 to 6), wherein a memory depth of the equalization function is L, wherein the equalization function is a combination of a plurality of basis functions, and wherein, for generating the equalized signal, the combiner circuit is configured to: determine a vector comprising L+1 samples from the received filtered signals as entries, L being an integer number; input the vector into the plurality of basis functions; and combine outputs of the plurality of basis functions for the input vector to generate a sample of the equalized signal.

Another example (e.g. example 8) relates to a previously described example (e.g. example 7), wherein the combiner circuit is configured to combine the outputs of the plurality of basis functions using a respective weight for the outputs of the plurality of basis functions.

Another example (e.g. example 9) relates to a previously described example (e.g. example 7 or example 8), wherein the number of the filters coupled in parallel is N, N being an integer number, wherein, if L<N, the vector comprises a respective sample at a sample position n from L+1 different ones of the received filtered signals as entries, and wherein, if L≥N, the vector comprises a respective sample at the sample position n from N different ones of the received filtered signals and L+1−N samples of different ones of the received filtered signals at one or more sample position preceding the sample position n as entries.

Another example (e.g. example 10) relates to a previously described example (e.g. any one of examples 7 to 9), wherein the combiner circuit is configured to generate the equalized signal according to a mathematical expression which is equivalent to:

$${z}_{n} = {\sum }_{k} {β}_{k} {f}_{k} ( {y}_{n}^{( 0 )} , {y}_{n}^{( 1 )} , … , {y}_{n - ⌊ \frac{L}{N} ⌋}^{( L - ⌊ \frac{L}{N} ⌋ N )} )$$

wherein zₙ denotes a sample of the equalized signal, ƒₖ denotes a respective one of the plurality of basis functions, βₖ denotes a respective weight,

$${y}_{n}^{( 0 )} , {y}_{n}^{( 1 )} , … , {y}_{n - ⌊ \frac{L}{N} ⌋}^{( L - ⌊ \frac{L}{N} ⌋ N )}$$

denotes the L+1 samples of the received filtered signals forming the vector, N denotes the number of the filters coupled in parallel, the subscript of each of zₙ and

$${y}_{n}^{( 0 )} , {y}_{n}^{( 1 )} , … , {y}_{n - ⌊ \frac{L}{N} ⌋}^{( L - ⌊ \frac{L}{N} ⌋ N )}$$

denotes a respective sample position of the respective sample, and the superscript of each of

$${y}_{n}^{( 0 )} , {y}_{n}^{( 1 )} , … , {y}_{n - ⌊ \frac{L}{N} ⌋}^{( L - ⌊ \frac{L}{N} ⌋ N )}$$

denotes a respective one of the N received filtered signals.

Another example (e.g. example 11) relates to a receiver, comprising: an apparatus according to a previously described example (e.g. any one of examples 1 to 10) and a non-linear system coupled to the apparatus and configured to output the digital input signal.

Another example (e.g. example 12) relates to a previously described example (e.g. example 11), wherein the non-linear system comprises an Analog-to-Digital Converter, ADC, configured to output the digital input signal.

Another example (e.g. example 13) relates to a previously described example (e.g. example 11 or example 12), wherein the non-linear system is configured to generate the digital input signal based on a radio frequency receive signal.

Another example (e.g. example 14) relates to base station, comprising a receiver according to a previously described example (e.g. any one of examples 11 to 13) and a transmitter configured to generate a radio frequency transmit signal.

Another example (e.g. example 15) relates to a previously described example (e.g. example 14), further comprising at least one antenna coupled to at least one of the receiver and the transmitter.

Another example (e.g. example 16) relates to mobile device comprising a receiver according to a previously described example (e.g. any of examples 11 to 13) and a transmitter configured to generate a radio frequency transmit signal.

Another example (e.g. example 17) relates to a previously described example (e.g. example 16), further comprising at least one antenna element coupled to at least one of the receiver and the transmitter.

Another example (e.g. example 18) relates to method for equalizing a digital input signal, comprising: receiving the digital input signal at an input node; filtering the digital input signal using a plurality of filters coupled in parallel to the input node to generate a respective filtered signal; receiving the respective filtered signal from the plurality of filters at a combiner circuit; and generating an equalized signal using the combiner circuit by combining the received filtered signals according to a non-linear equalization function.

Another example (e.g. example 19) relates to a previously described example (e.g. example 18), wherein a respective impulse response function of the plurality of filters is fixed.

Another example (e.g. example 20) relates to a previously described example (e.g. example 18 or example 19), wherein the plurality of filters are fractional delay filters.

Another example (e.g. example 21) relates to a previously described example (e.g. example 18), wherein filtering the digital input signal using the plurality of filters comprises delaying the digital input signal by a respective fractional of a sampling period time of the digital input signal by the plurality of fractional delay filters.

Another example (e.g. example 22) relates to a previously described example (e.g. example 20 or example 21), wherein filtering the digital input signal using the plurality of filters comprises delaying the digital input signal by zero times the sampling period time of the digital input signal by one of the plurality of fractional delay filters.

Another example (e.g. example 23) relates to a previously described example (e.g. any one of examples 18 to 22), wherein a sample rate of the equalized signal is equal to a sample rate of the digital input signal.

Another example (e.g. example 24) relates to a previously described example (e.g. any one of examples 18 to 23), wherein a memory depth of the equalization function is L, wherein the equalization function is a combination of a plurality of basis functions, and wherein generating the equalized signal comprises: determining a vector comprising L+1 samples from the received filtered signals as entries, L being an integer number; inputting the vector into the plurality of basis functions; and combining outputs of the plurality of basis functions for the input vector to generate a sample of the equalized signal.

Another example (e.g. example 25) relates to a previously described example (e.g. example 24), wherein the outputs of the plurality of basis functions are combined using a respective weight for the outputs of the plurality of basis functions.

Another example (e.g. example 26) relates to a previously described example (e.g. example 24 or example 25), wherein the number of the filters coupled in parallel is N, N being an integer number, wherein, if L<N, the vector comprises a respective sample at a sample position n from L+1 different ones of the received filtered signals as entries, and wherein, if L≥N, the vector comprises a respective sample at the sample position n from N different ones of the received filtered signals and L+1−N samples of different ones of the received filtered signals at one or more sample position preceding the sample position n as entries.

Another example (e.g. example 27) relates to a previously described example (e.g. any one of examples 24 to 26), wherein the equalized signal is generated according to a mathematical expression which is equivalent to:

$${z}_{n} = {\sum }_{k} {β}_{k} {f}_{k} ( {y}_{n}^{( 0 )} , {y}_{n}^{( 1 )} , … , {y}_{n - ⌊ \frac{L}{N} ⌋}^{( L - ⌊ \frac{L}{N} ⌋ N )} )$$

wherein zₙ denotes a sample of the equalized signal, ƒₖ denotes a respective one of the plurality of basis functions, βₖ denotes a respective weight,

$${y}_{n}^{( 0 )} , {y}_{n}^{( 1 )} , … , {y}_{n - ⌊ \frac{L}{N} ⌋}^{( L - ⌊ \frac{L}{N} ⌋ N )}$$

denotes the L+1 samples of the received filtered signals forming the vector, N denotes the number of the filters coupled in parallel, the subscript of each of zₙ and

$${y}_{n}^{( 0 )} , {y}_{n}^{( 1 )} , … , {y}_{n - ⌊ \frac{L}{N} ⌋}^{( L - ⌊ \frac{L}{N} ⌋ N )}$$

denotes a respective sample position of the respective sample, and the superscript of each of

$${y}_{n}^{( 0 )} , {y}_{n}^{( 1 )} , … , {y}_{n - ⌊ \frac{L}{N} ⌋}^{( L - ⌊ \frac{L}{N} ⌋ N )}$$

denotes a respective one of the N received filtered signals.

Another example (e.g. example 28) relates to non-transitory machine-readable medium having stored thereon a program having a program code for performing the method according to a previously described example (e.g. any one of examples 18 to 27), when the program is executed on a processor or a programmable hardware.

Another example (e.g. example 29) relates to a program having a program code for performing the method according to a previously described example (e.g. any one of examples 18 to 27), when the program is executed on a processor or a programmable hardware.

The aspects and features described in relation to a particular one of the previous examples may also be combined with one or more of the further examples to replace an identical or similar feature of that further example or to additionally introduce the features into the further example.

Examples may further be or relate to a (computer) program including a program code to execute one or more of the above methods when the program is executed on a computer, processor or other programmable hardware component. Thus, steps, operations or processes of different ones of the methods described above may also be executed by programmed computers, processors or other programmable hardware components. Examples may also cover program storage devices, such as digital data storage media, which are machine-, processor- or computer-readable and encode and/or contain machine-executable, processor-executable or computer-executable programs and instructions. Program storage devices may include or be digital storage devices, magnetic storage media such as magnetic disks and magnetic tapes, hard disk drives, or optically readable digital data storage media, for example. Other examples may also include computers, processors, control units, (field) programmable logic arrays ((F)PLAs), (field) programmable gate arrays ((F)PGAs), graphics processor units (GPU), application-specific integrated circuits (ASICs), integrated circuits (ICs) or system-on-a-chip (SoCs) systems programmed to execute the steps of the methods described above.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

1. An apparatus for equalizing a digital input signal, comprising:
an input node configured to receive the digital input signal;
a plurality of filters coupled in parallel to the input node, wherein the plurality of filters are configured to filter the digital input signal and generate a respective filtered signal; and
a combiner circuit coupled to the plurality of filters and configured to:
receive the respective filtered signal from the plurality of filters; and
generate an equalized signal by combining the received filtered signals according to a non-linear equalization function.

2. The apparatus of claim 1, wherein a respective impulse response function of the plurality of filters is fixed.

3. The apparatus of claim 1, wherein the plurality of filters are fractional delay filters.

4. The apparatus of claim 3, wherein the plurality of fractional delay filters are configured to delay the digital input signal by a respective fractional of a sampling period time of the digital input signal.

5. The apparatus of claim 3, wherein one of the plurality of fractional delay filters is configured to delay the digital input signal by zero times the sampling period time of the digital input signal.

6. The apparatus of claim 1, wherein a sample rate of the equalized signal is equal to a sample rate of the digital input signal.

7. The apparatus of claim 1, wherein a memory depth of the equalization function is L, wherein the equalization function is a combination of a plurality of basis functions, and wherein, for generating the equalized signal, the combiner circuit is configured to:
determine a vector comprising L+1 samples from the received filtered signals as entries, L being an integer number;
input the vector into the plurality of basis functions; and
combine outputs of the plurality of basis functions for the input vector to generate a sample of the equalized signal.

8. The apparatus of claim 7, wherein the combiner circuit is configured to combine the outputs of the plurality of basis functions using a respective weight for the outputs of the plurality of basis functions.

9. The apparatus of claim 7, wherein the number of the filters coupled in parallel is N, N being an integer number, wherein, if L<N, the vector comprises a respective sample at a sample position n from L+1 different ones of the received filtered signals as entries, and wherein, if L≥N, the vector comprises a respective sample at the sample position n from N different ones of the received filtered signals and L+1−N samples of different ones of the received filtered signals at one or more sample position preceding the sample position n as entries.

10. The apparatus of claim 7, wherein the combiner circuit is configured to generate the equalized signal according to a mathematical expression which is equivalent to:
$${z}_{n} = {\sum }_{k} {β}_{k} {f}_{k} ( {y}_{n}^{( 0 )} , {y}_{n}^{( 1 )} , … {y}_{n - ⌊ \frac{L}{N} ⌋}^{( L - ⌊ \frac{L}{N} ⌋ N )} )$$
wherein zₙ denotes a sample of the equalized signal, ƒₖ denotes a respective one of the plurality of basis functions, βₖ denotes a respective weight,
$${y}_{n}^{( 0 )} , {y}_{n}^{( 1 )} , … , {y}_{n - ⌊ \frac{L}{N} ⌋}^{( L - ⌊ \frac{L}{N} ⌋ N )}$$
denotes the L+1 samples of the received filtered signals forming the vector, N denotes the number of the filters coupled in parallel, the subscript of each of zₙ and
$${y}_{n}^{( 0 )} , {y}_{n}^{( 1 )} , … , {y}_{n - ⌊ \frac{L}{N} ⌋}^{( L - ⌊ \frac{L}{N} ⌋ N )}$$
denotes a respective sample position of the respective sample, and the superscript of each of
$${y}_{n}^{( 0 )} , {y}_{n}^{( 1 )} , … , {y}_{n - ⌊ \frac{L}{N} ⌋}^{( L - ⌊ \frac{L}{N} ⌋ N )}$$
denotes a respective one of the N received filtered signals.

11. A receiver, comprising:
an apparatus according to claim 1; and
a non-linear system coupled to the apparatus and configured to output the digital input signal.

12. The receiver of claim 11, wherein the non-linear system comprises an Analog-to-Digital Converter, ADC, configured to output the digital input signal.

13. The receiver of claim 11, wherein the non-linear system is configured to generate the digital input signal based on a radio frequency receive signal.

14. A base station, comprising:
a receiver according to claim 11; and
a transmitter configured to generate a radio frequency transmit signal.

15. A mobile device, comprising:
a receiver according to claim 11; and
a transmitter configured to generate a radio frequency transmit signal.

16. A method for equalizing a digital input signal, comprising:
receiving the digital input signal at an input node;
filtering the digital input signal using a plurality of filters coupled in parallel to the input node to generate a respective filtered signal;
receiving the respective filtered signal from the plurality of filters at a combiner circuit; and
generating an equalized signal using the combiner circuit by combining the received filtered signals according to a non-linear equalization function.

17. The method of claim 16, wherein a respective impulse response function of the plurality of filters is fixed.

18. The method of claim 16, wherein the plurality of filters are fractional delay filters.

19. The method of claim 18, wherein filtering the digital input signal using the plurality of filters comprises delaying the digital input signal by a respective fractional of a sampling period time of the digital input signal by the plurality of fractional delay filters.

20. The method of claim 18, wherein filtering the digital input signal using the plurality of filters comprises delaying the digital input signal by zero times the sampling period time of the digital input signal by one of the plurality of fractional delay filters.

21-25. (canceled)
